(19) United States
(12) Patent Application Publication
(10) Pub. No.: US 2025/0361137 A1
(43) Pub. Date: Nov. 27, 2025

(54) MICROELECTROMECHANICAL SYSTEMS (MEMS) INTEGRATION FOR ANALOG TUNABILITY IN RECONFIGURABLE INTELLIGENT SURFACES

(71) Applicant: Dell Products L.P., Round Rock, TX (US)

(72) Inventors: Navjot Kaur Khaira, Manotick (CA); Tejinder Singh, Manotick (CA)

(21) Appl. No.: 18/673,210

(22) Filed: May 23, 2024

(51) Int. Cl. B81B 3/00; B81C 1/00; H01Q 15/14

(52) U.S. Cl. CPC B81B 3/0037; B81C 1/0015; H01Q 15/148; B81B 2203/0118; B81B 2203/0307; B81B 2203/053; B81C 2201/0109; B81C 2201/013

(57) ABSTRACT

The technology described herein is directed towards a reconfigurable intelligent surface (RIS) based on microelectromechanical systems (MEMS) technology, in which MEMS micro-actuators are integrated into unit cells of the RIS. A ring-shaped cantilever, resulting from unit cell fabrication, operates as an electrothermal actuator in the unit cell's resonating pattern. A controlled voltage is applied to the ring-shaped cantilever, deforming (bending up) the metal (e.g., aluminum) ring at its non-anchored (free) portion from its relatively straight non-actuated state via joule heating. The amount of vertical displacement of the free portion of the ring when voltage is applied changes the structure of the unit cell's geometry based on the amount of voltage, whereby analog-like tuning of the unit cell's characteristics (including phase shift) is obtained. When combined with the voltage-controlled phase shifts of other unit cells of the RIS, beamforming of a reflected incoming electromagnetic wave is achieved.

### BACKGROUND

Reconfigurable intelligent surfaces (alternatively referred to metasurfaces) are manmade thin reflective or refractive surfaces with electronically adjustable properties that can manipulate electromagnetic waves. A reconfigurable intelligent surface is generally characterized by having a two-dimensional planar array of sub-wavelength structures, known as unit cells, whose characteristics are primarily dictated by the geometry of these structures. These elements are capable of altering the phase shift of the reflected signals, through active elements such as PIN diodes or varactors that tune electromagnetic responses, whereby through precise adjustment of these phase shifts, sophisticated reflect beamforming can be executed.

### BRIEF DESCRIPTION OF THE DRAWINGS

The technology described herein is illustrated by way of example and not limited in the accompanying figures in which like reference numerals indicate similar elements and in which:

FIG. 1 is a three-dimensional perspective view representation of an example unit cell of a reconfigurable intelligent surface for redirecting an incoming electromagnetic signal based on microelectromechanical systems (MEMS)-based phase control, in accordance with various example embodiments and implementations of the subject disclosure.

FIGS. 2A and 2B are side view representations of an example MEMS-based unit cell highlighting fabrication before and after removal of a sacrificial layer, respectively, in accordance with various example embodiments and implementations of the subject disclosure.

FIG. 2C is a side view representation of an example MEMS-based unit cell showing an example in which a cantilever is bent upwards as a result of joule heating, in accordance with various example embodiments and implementations of the subject disclosure.

FIGS. 3A and 3B are three-dimensional perspective view representations of an example MEMS-based unit cell showing a movable ring resonator's (cantilever's) vertical displacement in the absence of joule heating (zero applied voltage), and being bent upward when subject to joule heating (non-zero applied voltage), respectively, in accordance with various example embodiments and implementations of the subject disclosure.

FIG. 4 is a three-dimensional representation of an example 8×10 array of unit cells forming a reconfigurable intelligent surface, along with an enlarged section, and an enlarged unit cell of that enlarged section, showing curvature in a unit cell middle ring resulting from joule heating, in accordance with various example embodiments and implementations of the subject disclosure.

FIGS. 5A and 5B are side view representations of the example unit cell when voltage is applied, resulting in the vertical displacement of the movable ring due to joule heating, in accordance with various example embodiments and implementations of the subject disclosure.

FIG. 6A is an example three-dimensional perspective view representation of meshing a MEMS-based unit cell structure for finite element analysis, in accordance with various example embodiments and implementations of the subject disclosure.

FIG. 6B is an example three-dimensional perspective view representation of finite element analysis simulation showing the potential difference across the structure when a voltage difference of 6 V is applied across the anchors of the movable middle ring, in accordance with various example embodiments and implementations of the subject disclosure.

FIGS. 7A and 7B are example three-dimensional perspective view representations of the temperature of middle ring, and vertical displacement of the middle ring, respectively, as a result of some joule heating effect, in accordance with various example embodiments and implementations of the subject disclosure.

FIG. 8 is an example graphical representation of the normalized magnitude of downward displacement of the middle ring for different levels of applied voltage (Volts, in V), in accordance with various example embodiments and implementations of the subject disclosure.

FIG. 9A is an example graphical representation of magnitude of a unit cell at 40 GHz for varying voltages from 0 to 20 V with 4 V step size, in accordance with various example embodiments and implementations of the subject disclosure.

FIG. 9B is an example graphical representation of reflection phase of a unit cell at 40 GHz for varying voltage from 0 V to 20 V at the anchors with 4 V step size, in accordance with various example embodiments and implementations of the subject disclosure.

FIGS. 10A and 10B are example representations of beam steering of a reflected incoming electromagnetic wave in which reflected beam can be steered in desired target directions based on the voltages applied to the cantilevers/middle rings of the unit cells.

FIG. 11 is a flow diagram showing example operations related to controlling a bias voltage applied to a moveable element of a microelectromechanical systems-based resonating pattern to change a phase shift of a unit cell of a reconfigurable intelligent surface, in accordance with various example embodiments and implementations of the subject disclosure.

### DETAILED DESCRIPTION

The technology described herein is generally directed towards a reconfigurable intelligent surface of unit cells that includes dynamic control of the unit cells facilitated through the structural reconfiguration of unit-cell geometry using microelectromechanical systems (MEMS). In general, MEMS are miniature integrated devices or systems that combine electrical and mechanical components, which range in size from a few micrometers to millimeters, enabling technology to operate at a scale previously unachievable. Fabricated through microfabrication techniques akin to those in the semiconductor industry, MEMS devices offer mass production capabilities with high reliability and consistency at a relatively low cost. These versatile systems find extensive applications across various domains including automotive, consumer electronics, healthcare, and telecommunications. With reconfigurable intelligent surfaces falling within the millimeter or microscale range for millimeter-wave frequencies, MEMS integration as described herein is a very suitable platform.

In general, the technology described herein achieves unit cell reconfigurability in using electrothermally actuated MEMS. As will be understood, the technology involves multicycle operation of electrothermally reconfigurable MEMS using a cantilever-type ring structure composed of a material (e.g., aluminum) that curves as a result of joule heating when current flows through the material. The temperature-driven characteristics of the constituent material results in an overall out-of-plane deformation of the ring. This structural adaptation is highly effective in finely adjusting the individual electromagnetic properties of a reconfigurable intelligent surface's unit cells in real-time.

Structural reconfiguration of unit cell geometry using MEMS technology, by integrating MEMS actuators with unit cells of a reconfigurable intelligent surface as described herein, enables dynamic reshaping of unit cell geometries, facilitating tunable millimeter-wave response. The micro/millimeter scale dimensions of the MEMS actuator as described herein complement the size of unit cells at millimeter wave frequencies. This technology capitalizes on the structural displacement induced in the actuators under DC voltage bias, effectively altering the electromagnetic response of the unit cell.

The technology described herein achieves continuous tunability by adjusting the vertical displacement of a non-anchored portion of the movable ring within a unit cell metallic resonating pattern. Unlike approaches based on PIN diodes/varactors, which are limited to binary (1-bit) states in PIN diodes and six capacitance states in varactors, the utilization of MEMS out-of-plane actuators as described herein enables seamless, uninterrupted analog-type tuning over a large range. Electrothermal actuation provides significant displacement, thereby extending the tuning range. Through analog tuning of phase from individual unit cell, precise control over a reflected beam from a reconfigurable intelligent surface's unit cell array is achieved, enhancing adaptability and functionality across various applications.

The monolithic integration of MEMS actuators within reconfigurable intelligent surfaces as described herein provides significant advantages over traditional methods employing PIN diodes/varactors. Unlike these discrete components that need to be soldered onto the surface of the RIS, MEMS actuators can be seamlessly incorporated into the fabrication process, ensuring a more streamlined and efficient assembly. Moreover, the integration of MEMS within a reconfigurable intelligent surface eliminates the need for complex biasing and extensive wiring, simplifying the overall design and reducing potential points of failure. Additionally, MEMS integration with a reconfigurable intelligent surface offers compatibility with CMOS technology, further enhancing the feasibility and scalability of such systems.

It should be understood that any of the examples and/or descriptions herein are non-limiting. Thus, any of the embodiments, example embodiments, concepts, structures, functionalities or examples described herein are non-limiting, and the technology may be used in various ways that provide benefits and advantages in communications and computing in general.

Reference throughout this specification to “one embodiment,” “an embodiment,” “one implementation,” “an implementation,” etc. means that a particular feature, structure, characteristic and/or attribute described in connection with the embodiment/implementation can be included in at least one embodiment/implementation. Thus, the appearances of such a phrase “in one embodiment,” “in an implementation,” etc. in various places throughout this specification are not necessarily all referring to the same embodiment/implementation. Furthermore, the particular features, structures, characteristics and/or attributes may be combined in any suitable manner in one or more embodiments/implementations. Repetitive description of like elements employed in respective embodiments may be omitted for sake of brevity.

The detailed description is merely illustrative and is not intended to limit embodiments and/or application or uses of embodiments. Furthermore, there is no intention to be bound by any expressed or implied information presented in the preceding sections, or in the Detailed Description section. Further, it is to be understood that the present disclosure will be described in terms of a given illustrative architecture; however, other architectures, structures, materials and process features, and steps can be varied within the scope of the present disclosure.

It also should be noted that terms used herein, such as “optimize,” “optimization,” “optimal,” “optimally” and the like only represent objectives to move towards a more optimal state, rather than necessarily obtaining ideal results. Similarly, “maximize” means moving towards a maximal state (e.g., up to some processing capacity limit), not necessarily achieving such a state, and so on.

It will also be understood that when an element such as a layer, region or substrate is referred to as being “on” or “over” “atop” “above” “beneath” “below” and so forth with respect to another element, it can be directly on the other element or intervening elements can also be present. In contrast, only if and when an element is referred to as being “directly on” or “directly over” another element, are there no intervening element(s) present. Note that orientation is generally relative; e.g., “on” or “over” can be flipped, and if so, can be considered unchanged, even if technically appearing to be under or below/beneath when represented in a flipped orientation. It will also be understood that when an element is referred to as being “connected” or “coupled” to another element, it can be directly connected or coupled to the other element or intervening elements can be present. In contrast, only if and when an element is referred to as being “directly connected” or “directly coupled” to another element, are there no intervening element(s) present.

The following detailed description is merely illustrative and is not intended to limit embodiments and/or application or uses of embodiments. Furthermore, there is no intention to be bound by any expressed or implied information presented in the preceding sections, or in the Detailed Description section.

One or more example embodiments are now described with reference to the drawings, in which example components, graphs and/or operations are shown, and in which like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details, and that the subject disclosure may be embodied in many different forms and should not be construed as limited to the examples set forth herein.

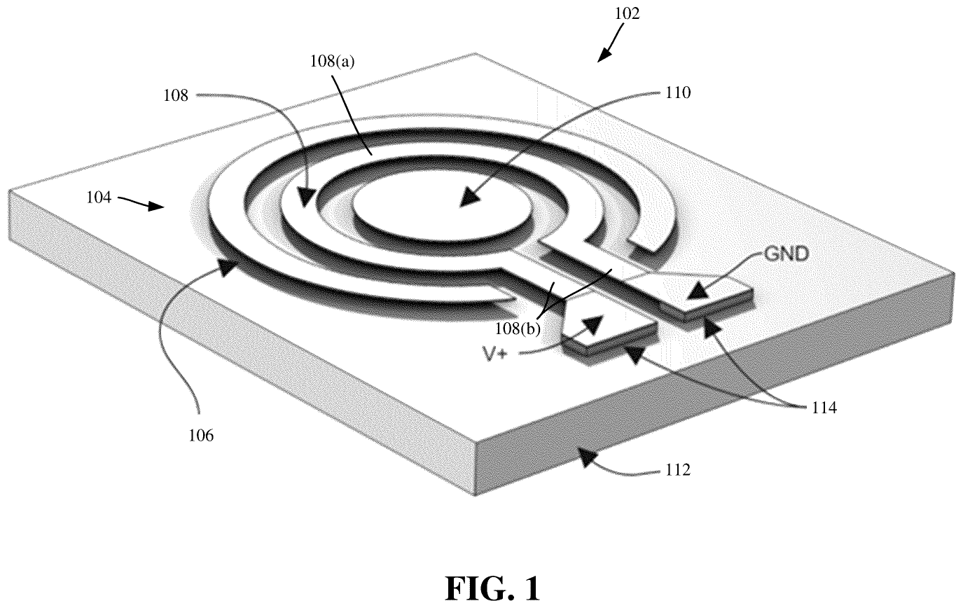

FIG. 1 is a three-dimensional perspective representation of an example unit cell 102 of a type that redirects (reflects or refracts) incoming electromagnetic signals. The unit cell 102, in conjunction with other unit cells, forms a reconfigurable intelligent surface. In general, the reflective surface is formed by a two-dimensional periodic array of such unit cells.

In one implementation, the unit cell 102 includes a resonating pattern 104 of metallic elements, such as including a generally ring-shaped resonator pattern configured to resonate when the incoming electromagnetic (EM)/radio frequency (RF) wave is impinging on the unit cell 102, such as an RF signal near or within the millimeter wavelength, e.g., (above 25 gigahertz) or higher. In general, the metallic resonating pattern is designed to resonate at a frequency that corresponds to the frequency of the incoming signal. As set forth herein, a unit cell 102 can have a resonating pattern 104 of any suitable shape (e.g., square, rectangular, concentric ring-shape, coupled circles and so on) that resonates at a corresponding frequency of the incoming signal, and is thus not limited to any particular pattern. Note that in the examples herein, a unit cell 102 is designed for operation at 37-45 GHz; notwithstanding, the technology described herein can be easily extended to other frequency ranges.

In general, the metallic resonating pattern 104 is designed for operation at a desired resonance frequency that corresponds to the frequency of the incoming signal. More particularly, FIG. 1 shows a unit cell 102 for a reconfigurable millimeter wave (mmWave) reflective surface that is based on using a microelectromechanical systems (MEMS) actuator to achieve the dynamic tuning of the reflection phase. The unit cell structure 102 has the metallic pattern 104 generally shaped like a bullseye, which includes metallic concentric circular (e.g., penannular) rings, an outer ring 106 and an inner ring 108, surrounding an inner (center) disk 110 fixed to a substrate 112. At least the inner ring 108 is made from a bendable material as described herein.

As described herein, the outer ring 106 is fixed, while the inner ring 108 is bendable (movable) in a vertical direction at one portion 108 (a) thereof, and fixed at the opposite (extended) portion 108 (b) by two anchors 114 coupled to opposite extended sides of the penannular inner ring 108, whereby the inner ring 108 is a cantilever. These anchors 114 can incorporate, or can be coupled to, electrical contacts for applying a bias voltage (or current) across the contacts, resulting in joule heating of the inner ring 108 that, in one implementation, bends the inner ring upward from a substantially parallel (to the substrate 112) state away from the substrate 112 in an amount corresponding to the applied voltage. Note that although not explicitly shown in FIG. 1, the electrical contacts can be beneath the substrate 112, and, for example, extend through a ground plane of the reconfigurable intelligent surface by vias, one of which is electrically insulated from the ground plane to carry the positive voltage to one side of the inner ring 108; the other via couples the opposite side of inner ring 108 to ground/the ground plane.

In general, MEMS technology has enabled a wide variety of micro-actuators with varied performance in terms of deformation range, reconfiguration direction, response time, power consumption, ease of integration and CMOS compatibility. These micro-actuators, including cantilevers, beams, diaphragms, and frames, enable mechanical deformation under external stimuli, hence the designation of ‘micro-actuators’.

Described herein is a micro-actuator based on the cantilever actuator, characterized by its thin, rigid structure anchored at one end with free movement at the other end. During the fabrication process, a sacrificial layer is often used to facilitate the creation of free-standing structures like cantilevers. These sacrificial layers provide temporary support during fabrication and are later removed to release the desired structures. This suspended cantilever beam offers versatility in actuation mechanisms, including thermal, electrostatic, piezoelectric, electrothermal, and electromagnetic methods. Electrothermal actuation as described herein harnesses thermal expansion of MEMS cantilevers.

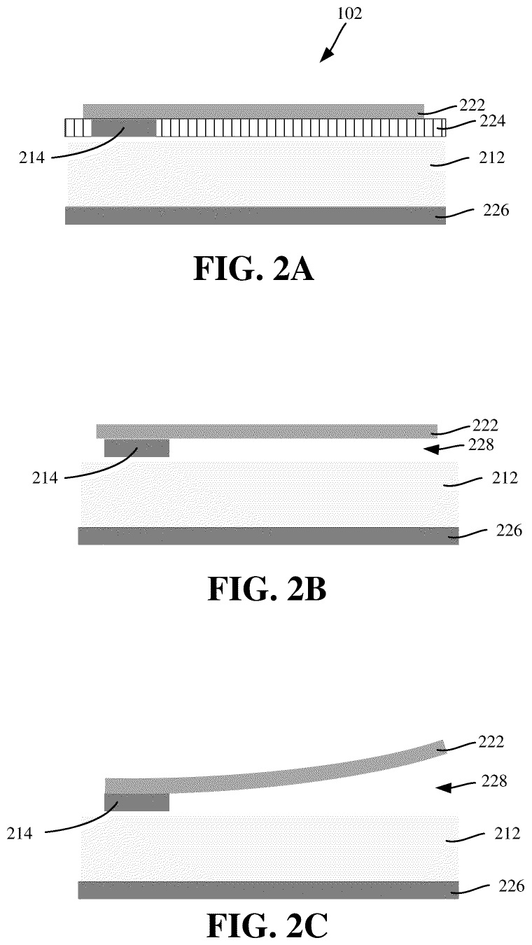

In one nonlimiting implementation, the metallic pattern 104 is made from a thin layer of aluminum (Al), which is the top layer 222, as shown in the fabrication cross-section in FIG. 2A. This facilitates efficient fabrication, as all metallic pattern layers can be the same materials, and/or the same thicknesses. In the layer stack of FIG. 2A, going from top to bottom, the top aluminum layer 222 is on the top of a sacrificial layer 224 of silicon dioxide (SiO2), which sits on a silicon (Si) substrate 212. The anchor layer 214, at the same level as the sacrificial layer, 224 can be aluminum or other suitable material. The bottom surface of the substrate 212 is coated with a thin metal (such as aluminum or some other metal like copper) 226.

Note that while aluminum is used herein in the examples, any suitable material can be used. In the examples herein, using purely CMOS compatible processes and materials, the reconfigurable intelligent surface patterns are made of aluminum layers.

The sacrificial layer 224 is selectively removed from underneath the middle ring (108 in FIG. 1, layer 222 in FIG. 2A), resulting in a cantilever by leaving an air gap 228 on one side of the cantilever/aluminum layer 222 after release as shown in FIG. 2B. The other side of the aluminum layer 222 remains attached to the substrate 212 via the anchors 214 on one end.

As will be understood, joule heating results in electrothermal actuation, such as to curve the aluminum layer 222 upward based on the amount of joule heating, as generally represented in FIG. 2C. Note that the vertical displacement increases, as apparent from the larger air gap 228 in the actuated state shown in FIG. 2C, relative to the non-actuated state in FIG. 2B. Although not shown, it is feasible to have a metallic ring that bends downward in response to joule heating, e.g., in an alternative implementation, the cantilever can be angled somewhat upward when non-actuated, and bent downward when subject to joule heating, which also will change the unit cell geometry.

To summarize, material such as aluminum atop a silicon (Si) substrate, is initially supported by a sacrificial layer of silicon dioxide. A subsequent fabrication step involves selectively etching away the sacrificial layer beneath the inner middle ring (while not fully etching away the outer ring/disk, if not otherwise anchored, so that they remain fixed to the substrate). This makes one portion of the middle ring hang above the substrate, with the other portion physically coupled to the substrate two fixed anchors, which also can act as bias pads. This structure acts somewhat similar to a MEMS cantilever design. A voltage difference provided to these anchors causes joule heating effect in the thin floating metal ring, resulting in out-of-plane displacement or curved motion of the middle ring's free end.

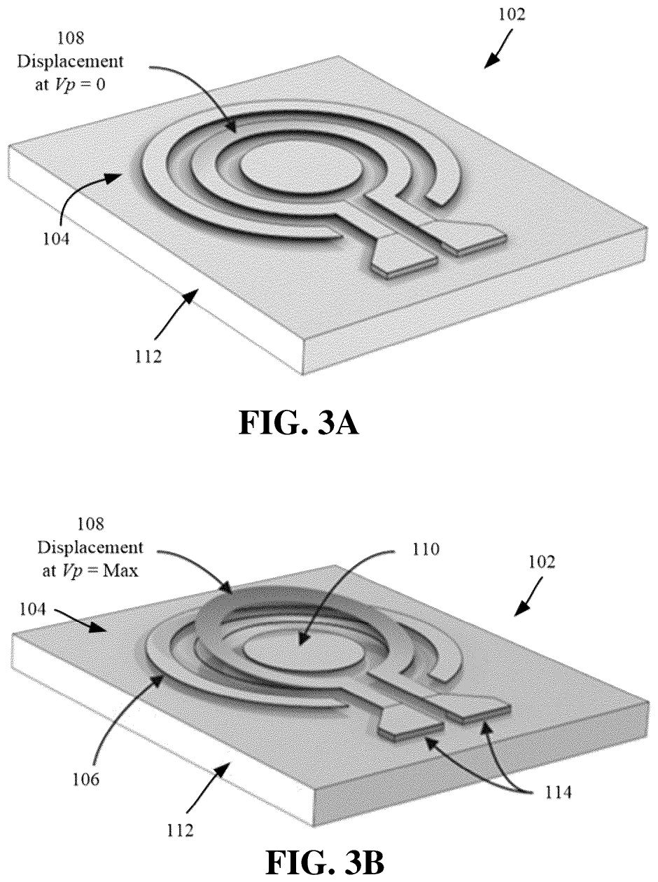

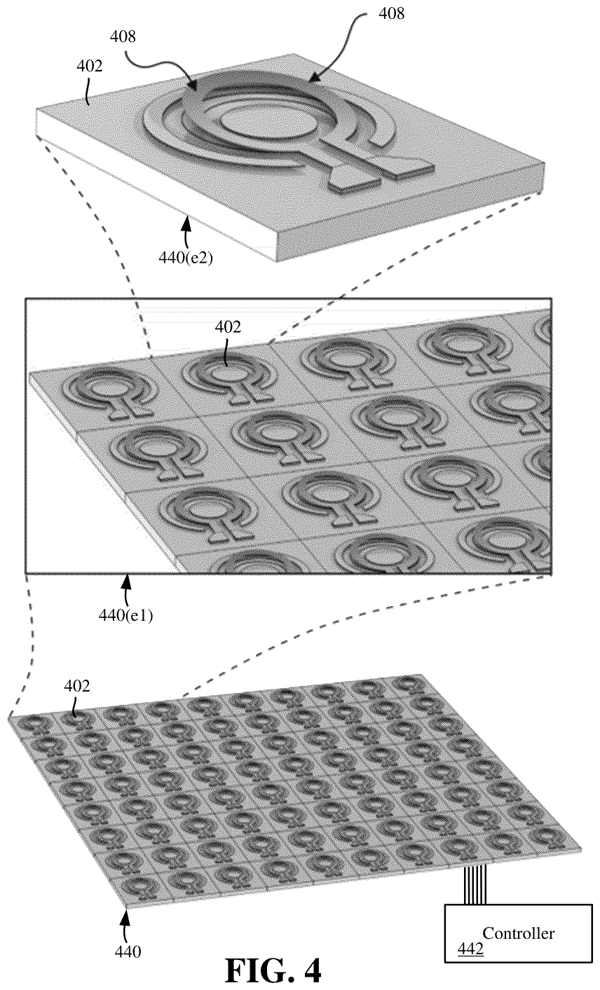

More particularly, when a voltage difference is applied across the anchor pads, e.g., as controlled by a controller 442 (FIG. 4), the resulting current through the metallization middle ring 108 causes the joule heating effect, resulting in out-of-plane displacement or curved motion of the middle ring's free end. A suspended structure (the non-anchored portion of the cantilever) bends upwards with increasing temperature, that is, the deformation in the actuated state causes the middle ring to curve upwards relative to its non-actuated state. The extreme examples are shown in FIG. 3A (zero voltage, no bend/no additional vertical displacement) compared to FIG. 3B (highest applied voltage, largest bend/maximum vertical displacement). To reiterate, his structural deformation under the effect of temperature caused by electrical voltage is called electrothermal actuation.

FIG. 4 shows a reconfigurable intelligent surface 440 that is a made of an array of unit cells; one such unit cell 402 is labeled. As can be seen from the enlarged views 440(e1) and 440(e2) (showing the voltage/joule heating bending in the thin flexure ring), the metallization middle ring 408 of the bullseye structure is bent upwards because of joule heating.

Temperature driven expansion of the metal layer results in an overall out-of-plane deformation of the cantilever. Hence, the actuation method is electrothermal, which offers larger stroke and higher repeatability. Multicycle operation of electrothermally reconfigurable MEMS RIS is achieved using such thin metal cantilevers.

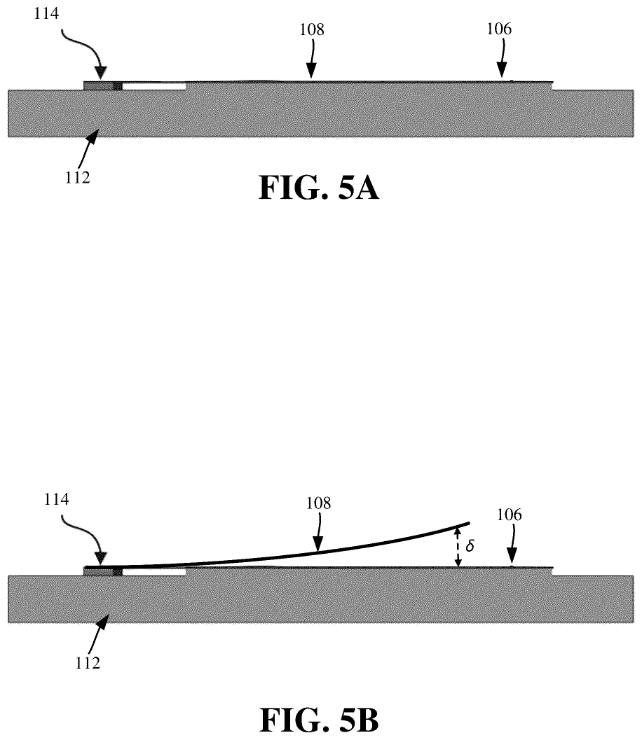

FIG. 5A shows a unit cell in the non-actuated state of zero applied volts, while FIG. 5B shows the vertical displacement, δ, of the tip of the cantilever type ring under electrothermal actuation due to thermal expansion from applied voltage/joule heating without any other external forces applied. The vertical displacement δ can be derived from the thermal expansion equation and the bending moment equation:

$$δ = αΔ {TD}^{2} \frac{1}{2 R}$$

where α refers to coefficient of thermal expansion (α=23.1×10⁻⁶−K⁻¹ for aluminum), ΔT is the change in temperature due to Joule heating, D is the outside diameter of the displacement ring, and R is the radius of curvature of the bent cantilever due to thermal expansion. Note that this is a simplified expression that does not consider the width of the ring and Young's modulus, which brings bending stiffness of the ring into picture. Incorporating these factors into the above equation makes it significantly more complex and often requires numerical methods for precise solutions.

To summarize, when electrical voltage is applied to the anchor pads, the temperature of the middle ring increases due to joule heating. This causes the aluminum to bend, that is, the suspended portion of the ring bends upwards away from the substrate with increasing temperature, such that the vertical displacement δ is increased based on the applied voltage. This continuous structural deformation drives a shift in the resonance frequency of the unit cell towards higher frequencies. Consequently, an incident electromagnetic wave reflects off the two-dimensional array of such reconfigurable intelligent surface unit cells, exhibiting varying phase values determined by the structural displacement in each cell. These individually controllable phase values can thus be used for constructive/destructive interference to beamform the reflected electromagnetic wave.

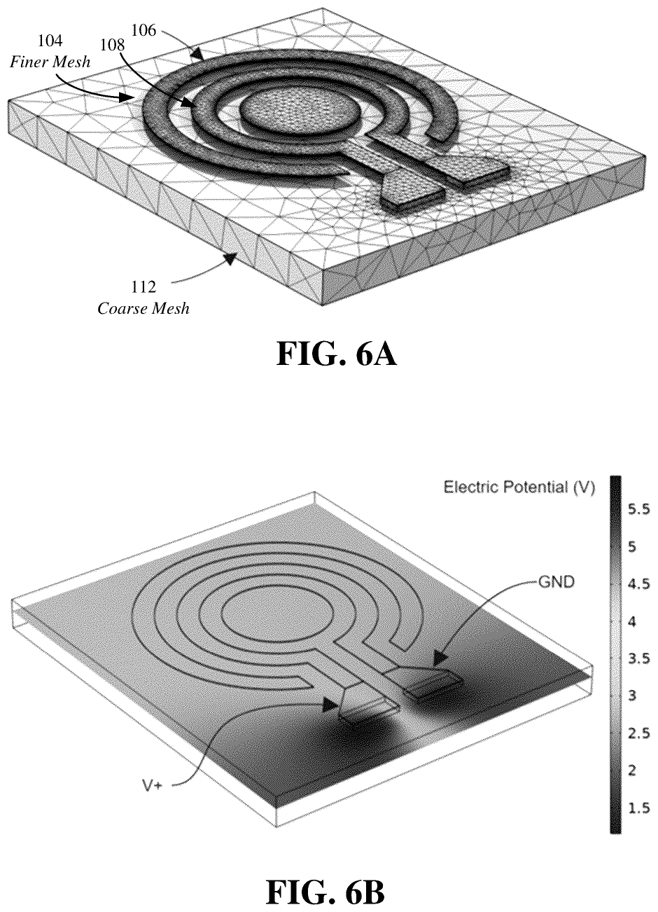

Turning to an analysis, a finite element analysis tool (e.g., COMSOL MULTIPHYSICS) can be used; note that the interactions between thermal expansion, material stiffness, and geometric dimensions lead to nonlinear effects that are not easily captured in a closed-form equation. In general, finite element analysis involves dividing a continuous domain into smaller, simpler elements, referred to as the meshing as shown in FIG. 6A. Finite element analysis solves partial differential equations, which are discretized over the elements of the mesh to approximate the behavior of the system; (note that without meshing, it would be highly impractical to solve these equations numerically). The finer the mesh, the more accurate the response generated, e.g., the substrate 112 has a coarse mesh, whereas the elements of the resonating pattern 104 have a finer mash.

To evaluate the displacement of the middle ring that acts like a cantilever, voltage differences from 0 V to 20 V is applied on the anchors. FIG. 6B shows potential difference across the structure when a voltage difference of 6 V is applied across the anchors of the middle ring.

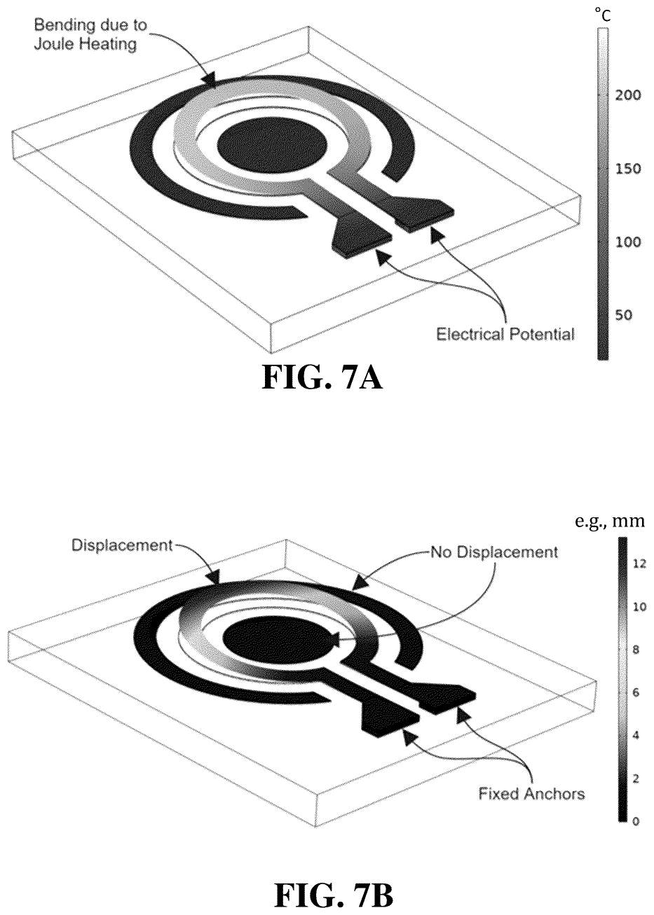

To study the displacement of the middle ring that acts like a cantilever, a voltage difference is applied on the anchors starting from 0 V up to 20 V in incremental steps of 1 V. FIG. 6B shows the voltage difference in a simulation setup. When electrical current passes through the thin aluminum ring, the temperature of the entire reconfigurable intelligent surface unit cell increases due to joule heating as shown in FIG. 7A. This rise in temperature leads to the upward deformation of middle ring as shown in FIG. 7B. Note that the maximum voltage that is applied corresponds to a maximum joule heating temperature that is far less than the melting point of aluminum of 660 degrees Celsius (° C.).

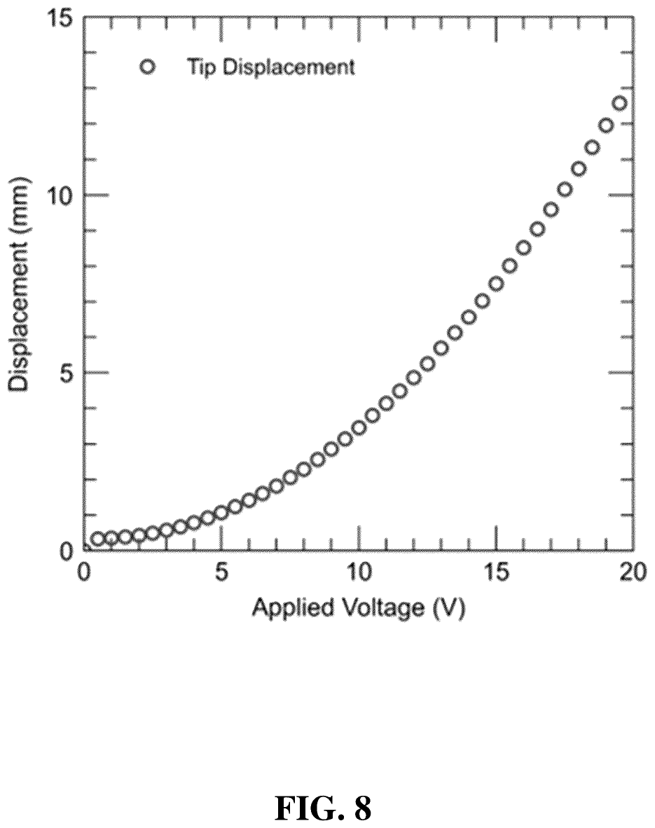

As the voltage is decreased (the device starts to cool down), the ring starts coming back downwards, highlighting the repeatability of the operation. The curve in FIG. 8 shows the normalized displacement at the tip of the ring achieved with the applied voltage. The curve in FIG. 8 shows the displacement at the tip of the ring achieved with the applied voltage. It is observed that for an applied voltage of 20 V, the corresponding displacement (e.g., of 13 mm in one implementation, although different implementations will have different dimensions) is attained, which is very large and can provide good tunability in the resonance frequency of the structure.

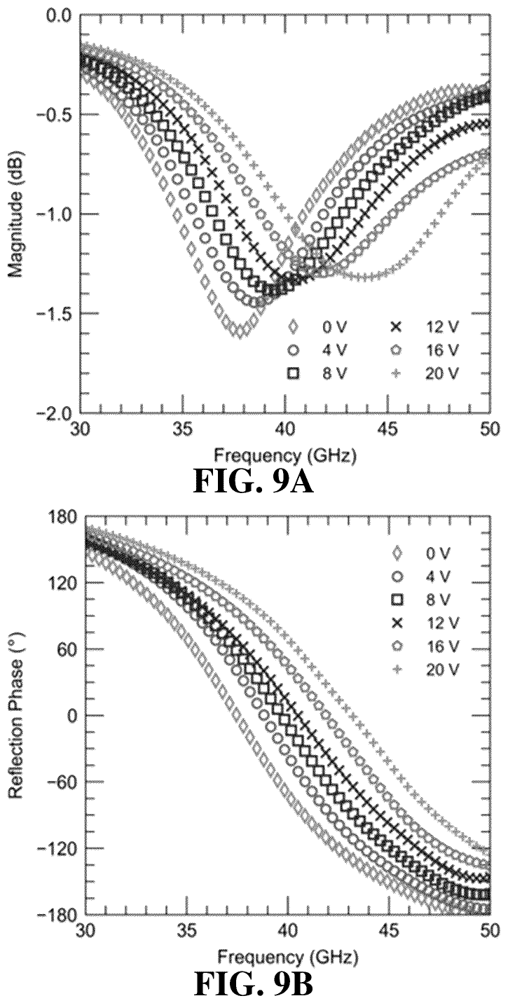

Full wave analysis can be done in 3D electromagnetic simulation software (e.g., Ansys HFSS) to extract the reflection characteristics of the unit cell for the tuning range. Periodic boundary conditions can be used during simulation of the cell, which assume an infinite structure. A parametric simulation can be done for different displacement levels of the ring cantilever by adjusting the applied voltage. The resonance frequency is at 37 GHz when the ring is suspended after the sacrificial layer etching; this non-actuated state corresponds to a voltage supply of 0 V. Continuous tuning is observed in the resonant frequency with respect to the input voltage. When the voltage is 20 V, the resonant frequency is at 45 GHz as shown in FIGS. 9A and 9B.

The reason for this phenomenon is that the resonant frequency of the reconfigurable intelligent surface structure can be given as:

$$ω = \sqrt{\frac{1}{L C}} ,$$

where L and C refer to the effective inductance and capacitance in the reconfigurable intelligent surface structure that enables coupling of the incident electromagnetic wave. It can be quantitatively seen that as the ring bends away from the substrate, the gap between the metal and the substrate increases. This decreases the capacitance, whereby the resonance frequency increases. Compared to an electrostatic actuation mechanism, a larger range of motion can be achieved by using electrothermal actuation, which causes a larger shift in the resonance frequency and the corresponding output phase.

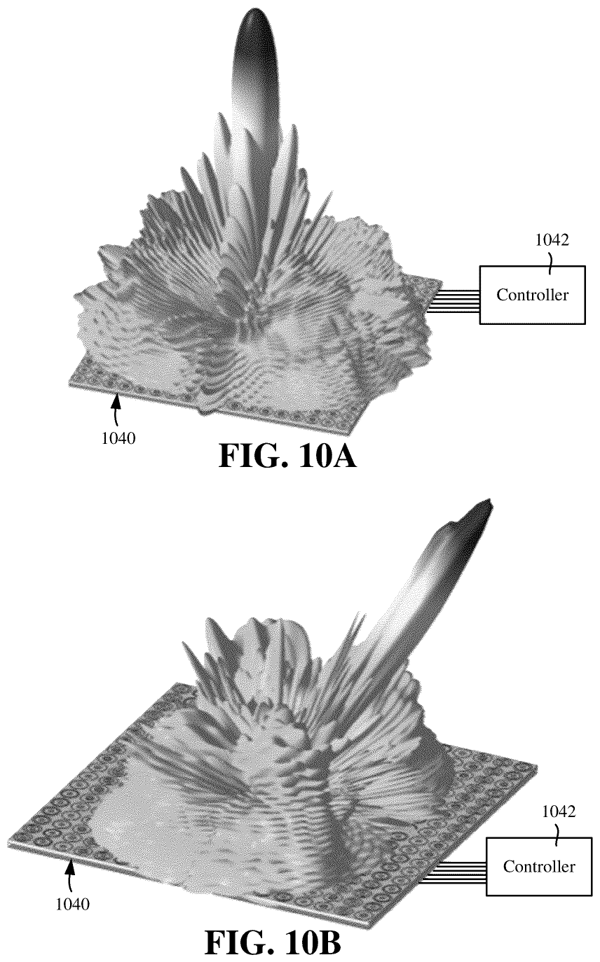

This change in phase from individual unit cell leads to constructive/destructive interference in the desired direction when combined into an array to form a reconfigurable intelligent surface panel. Such beam steering is shown in FIGS. 10A and 10B in which the reflected beam can be steered in a desired direction based on the voltages applied to the cantilever rings of the unit cells. More particularly, for redirecting impinging signals, the reconfigurable intelligent surface 1040 is coupled to or otherwise incorporates the controller 1042 that controls the phase shifts of the unit cells designed for signal redirection by applying appropriate voltages (e.g., from zero volts to the maximum voltage) to the unit cells to deform respective middle rings to change their respective phases, facilitating constructive (or destructive interference) for beamforming. Beamforming allows the incoming electromagnetic wave/signal to be redirected (reflected or refracted) as a beam that can be shaped and steered in a desired direction, as shown in FIG. 10A (one set of respective voltages for the respective unit cells), and 10B (another set of respective voltages for the respective unit cells).

To summarize, the MEMS-based actuator for a reconfigurable unit cell offers a higher tuning range, larger stroke, and enhanced repeatability compared to other unit cell technologies, achieving a maximum tuning range of approximately 8 GHz with a 20 V input voltage. This electrothermal approach is particularly effective for applications needing substantial displacements and force outputs at the millimeter/microscale device level.

One or more example embodiments can be embodied in a unit cell device, such as described and represented herein. The unit cell device can include a microelectromechanical systems (MEMS)-based resonating pattern on a substrate, which can include a fixed resonating portion, a metallic cantilever comprising an anchored portion and a non-anchored portion, the metallic cantilever having a first vertical displacement relative to the substrate at a tip of the non-anchored portion of the metallic cantilever, in response to the metallic cantilever being in a non-actuated state, and electrical contact pads electrically coupled to the metallic cantilever. Energy applied via the electrical contact pads can change the non-actuated state of the metallic cantilever to an actuated state that bends the non-anchored portion of the metallic cantilever to change the first vertical displacement distance at the tip to a second vertical displacement distance that is based on an amount of the energy applied. In response to an impinging electromagnetic wave on the unit cell device, the resonating pattern resonates to redirect an instance of the electromagnetic based on a phase shift determined by the first vertical displacement distance in response to the metallic cantilever being in the non-actuated state, and the second vertical displacement distance in response to the metallic cantilever being in the actuated state.

In the non-actuated state, the metallic cantilever is substantially unbent and is substantially parallel to the substrate, and in the actuated state, the metallic cantilever can bend upward relative to the substrate; the first vertical displacement distance can be less than the second vertical displacement distance.

In the non-actuated state, the metallic cantilever is substantially unbent, and in the actuated state, the metallic cantilever can bend downward relative to the substrate; the first vertical displacement distance can be greater than the second vertical displacement distance.

The energy applied via the electrical contact pads can include a bias voltage applied across the electrical contact pads, and the amount of the energy applied can be based on a bias voltage level.

The bias voltage can include a first bias voltage, the phase shift can be a first phase shift based on the first bias voltage, and a second voltage applied across the electrical contact pads can determine a second phase shift that is different from the first phase shift.

The metallic cantilever can include aluminum.

The fixed resonating portion can include a fixed outer penannular ring and a fixed disk physically coupled to the substrate, and the metallic cantilever can include an inner penannular ring positioned between the outer penannular ring and the fixed disk. A gap of the inner penannular ring can include a first side physically coupled to a first anchor of the anchored portion, and a second side physically coupled to a second anchor of the anchored portion; the electrical contact pads can include a first electrical contact pad coupled to the first anchor, and a second electrical contact pad coupled to the second anchor.

The redirected instance can be a first redirected instance, the unit cell device can be part of a reconfigurable intelligent surface that can include the unit cell and other unit cells arranged in an array that forms the reconfigurable intelligent surface, and the phase shift of the unit cell device can redirect the first redirected instance of the electromagnetic wave in a direction that creates constructive interference with a second redirected instance of the electromagnetic wave as redirected from at least one other of the other unit cells.

The fixed resonating portion and the metallic cantilever can be fabricated above a sacrificial layer, in which the sacrificial layer can be partially removed by sacrificial layer etching with respect to the fixed resonating portion, resulting in the fixed layer being physically coupled to the substrate, and in which the sacrificial layer can be fully removed with respect to the non-anchored portion of the metallic cantilever, resulting in an air gap between the non-anchored portion of the metallic cantilever and the substrate.

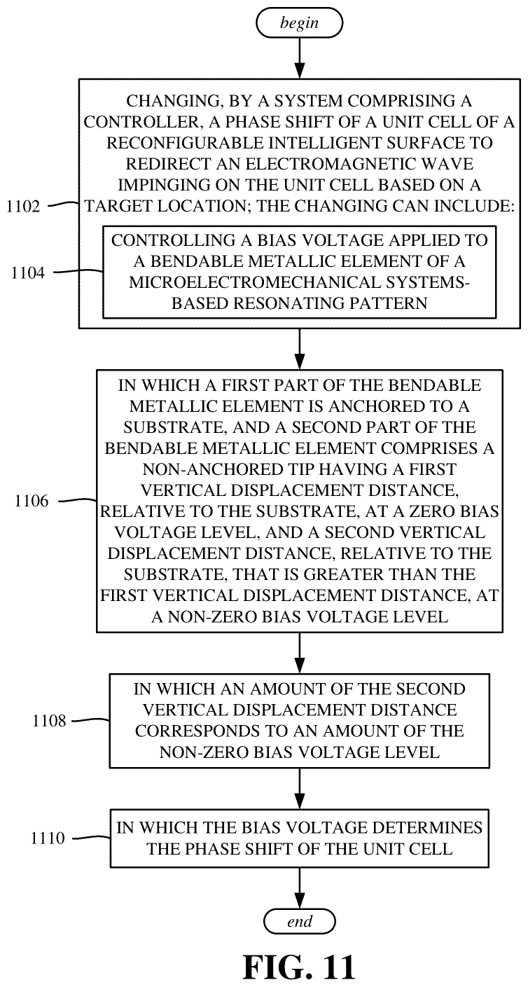

One or more example aspects, such as corresponding to example operations of a method, or a system/a machine-readable medium having executable instructions that, when executed by a controller, facilitate performance of the operations, are represented in FIG. 11. Example operation 1102 represents changing, by a system comprising a controller, a phase shift of a unit cell of a reconfigurable intelligent surface to redirect an electromagnetic wave impinging on the unit cell based on a target location. The changing can include example operation 1104, which represents controlling a bias voltage applied to a bendable metallic element of a microelectromechanical systems-based resonating pattern, in which (example block 1106) a first part of the bendable metallic element is anchored to a substrate, and a second part of the bendable metallic element comprises a non-anchored tip having a first vertical displacement distance, relative to the substrate, at a zero bias voltage level, and a second vertical displacement distance, relative to the substrate, that is greater than the first vertical displacement distance, at a non-zero bias voltage level. At example block 1108, amount of the second vertical displacement distance corresponds to an amount of the non-zero bias voltage level. At example block 1110, the bias voltage determines the phase shift of the unit cell.

The phase shift can be a first phase shift, the target location can be a first target location, and further operations can include obtaining, by the system, information representative of a second target location, and in response to the obtaining of the information, redirecting, by the system, the electromagnetic wave based on the second location, which can include changing the bias voltage from a first bias voltage to a second bias voltage to change the first phase shift to a second phase shift that is different from the first phase shift.

The unit cell can be part of a reconfigurable intelligent surface that can include the unit cell and other unit cells arranged in an array that forms the reconfigurable intelligent surface, and changing the phase shift of the unit cell based on the target location can redirect the electromagnetic wave to create constructive interference with the electromagnetic wave as redirected from at least one of the other unit cells, with respect to beamforming the electromagnetic wave as redirected towards the target location.

The unit cell can be part of a reconfigurable intelligent surface that can include the unit cell and other unit cells arranged in an array that forms the reconfigurable intelligent surface, and changing the phase shift of the unit cell based on the target location can create destructive interference with the electromagnetic wave as redirected from at least one of the other unit cells.

One or more example embodiments can be embodied in a system, such as described and represented herein. The system can include a unit cell configured to redirect an incoming electromagnetic wave as a redirected electromagnetic wave. The unit cell can include a substrate, and a resonating pattern corresponding to the incoming electromagnetic wave. The resonating pattern can include a fixed metallic resonator, and a metallic cantilever, which can include a first portion physically coupled to the substrate, and a second portion physically decoupled from the substrate. The metallic cantilever can be substantially uncurved when not heated by joule heating, relative to a greater amount of curvature when heated by a non-zero amount of joule heating, in which a resultant amount of curvature corresponds to the amount of joule heating. Electrical contacts can be coupled to the metallic cantilever proximate to the first portion. A controller can be configured to selectively apply energy to the electrical contacts to selectively heat the metallic cantilever with a selected amount of joule heating, corresponding to a selected resultant amount of curvature of the metallic cantilever, in which the resultant amount of curvature determines a direction of the redirected electromagnetic wave.

The first portion of the metallic cantilever can be physically coupled to the substrate by respective anchors, and the respective anchors can be electrically coupled to respective electrical contacts of the electrical contacts.

The controller can apply a selected bias voltage or current to the electrical contacts to heat the metallic cantilever with the selected amount of joule heating.

The metallic cantilever can include aluminum.

The fixed resonating portion can include a fixed outer penannular ring, and further can include a fixed disk physically coupled to the substrate; the cantilever can include an inner penannular ring positioned between the outer penannular ring and the fixed disk.

the unit cell can be a first unit cell of a reconfigurable intelligent surface that can include the first unit cell and a second unit cell, the selected amount of joule heating can be a first selected amount, the redirected electromagnetic wave can be a first redirected electromagnetic wave, the direction of the first redirected electromagnetic wave can be a first direction, and the controller can select the first selected amount of joule heating for the first unit cell, and select a second selected amount of joule heating for the second unit cell, to create constructive interference of the first redirected electromagnetic wave with a second redirected electromagnetic wave as redirected from the second unit cell in a second direction.

As can be seen, the technology described herein is directed to a reconfigurable intelligent surface that integrates MEMS micro-actuators within the reconfigurable intelligent surface's unit cells, facilitating dynamic reshaping of unit cell geometries without the need for PIN diodes/varactors. By combining MEMS and reconfigurable intelligent surface technologies as described herein, the example unit cells designs facilitate MEMS integration with a reconfigurable intelligent surface that overcomes many current limitations in reconfigurable intelligent surface technologies, facilitating advanced wireless communication solutions. By seamlessly integrating MEMS with reconfigurable intelligent surface designs, e.g., during the fabrication process, active tuning capabilities result from the integration of bias networks, without the need for on-chip soldering of components and hence eliminating any intricate wiring complexities.

In one implementation, each reconfigurable intelligent surface unit cell includes a distinctive metallic pattern resembling a bullseye, characterized by a central disk encircled by two concentric rings. The inner ring is anchored at one portion and free at the opposite portion, resulting in a cantilever that is vertically deformed by joule heating. Control of the amount of vertical displacement via a continuously tunable millimeter-wave unit cell can be accomplished by applying an analog voltage to heat the material. Consequently, an incident electromagnetic wave reflects off the two-dimensional array of such unit cells in a controlled direction based on the varying phase values determined by the structural displacement in each cell.

The above description of illustrated embodiments of the subject disclosure, comprising what is described in the Abstract, is not intended to be exhaustive or to limit the disclosed embodiments to the precise forms disclosed. While specific embodiments and examples are described herein for illustrative purposes, various modifications are possible that are considered within the scope of such embodiments and examples, as those skilled in the relevant art can recognize.

In this regard, while the disclosed subject matter has been described in connection with various embodiments and corresponding Figures, where applicable, it is to be understood that other similar embodiments can be used or modifications and additions can be made to the described embodiments for performing the same, similar, alternative, or substitute function of the disclosed subject matter without deviating therefrom. Therefore, the disclosed subject matter should not be limited to any single embodiment described herein, but rather should be construed in breadth and scope in accordance with the appended claims below.

As used in this application, the terms “component,” “system,” “platform,” “layer,” “selector,” “interface,” and the like are intended to refer to a computer-related resource or an entity related to an operational apparatus with one or more specific functionalities, wherein the entity can be either hardware, a combination of hardware and software, software, or software in execution. As an example, a component can be an apparatus with specific functionality provided by mechanical parts operated by electric or electronic circuitry. As yet another example, a component can be an apparatus that provides specific functionality through electronic components without mechanical parts, the electronic components can comprise a processor therein to execute software or firmware that confers at least in part the functionality of the electronic components.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances.

While the embodiments are susceptible to various modifications and alternative constructions, certain illustrated implementations thereof are shown in the drawings and have been described above in detail. It should be understood, however, that there is no intention to limit the various embodiments to the specific forms disclosed, but on the contrary, the intention is to cover all modifications, alternative constructions, and equivalents falling within the spirit and scope.

In addition to the various implementations described herein, it is to be understood that other similar implementations can be used or modifications and additions can be made to the described implementation(s) for performing the same or equivalent function of the corresponding implementation(s) without deviating therefrom. Still further, multiple processing chips or multiple devices can share the performance of one or more functions described herein, and similarly, storage can be effected across a plurality of devices. Accordingly, the various embodiments are not to be limited to any single implementation, but rather are to be construed in breadth, spirit and scope in accordance with the appended claims.

What is claimed is:

1. A unit cell device, comprising:
a microelectromechanical systems (MEMS)-based resonating pattern on a substrate, comprising:
a fixed resonating portion;
a metallic cantilever comprising an anchored portion and a non-anchored portion, the metallic cantilever having a first vertical displacement relative to the substrate at a tip of the non-anchored portion of the metallic cantilever, in response to the metallic cantilever being in a non-actuated state; and
electrical contact pads electrically coupled to the metallic cantilever,
wherein energy applied via the electrical contact pads changes the non-actuated state of the metallic cantilever to an actuated state that bends the non-anchored portion of the metallic cantilever to change the first vertical displacement distance at the tip to a second vertical displacement distance that is based on an amount of the energy applied, and
wherein, in response to an impinging electromagnetic wave on the unit cell device, the resonating pattern resonates to redirect an instance of the electromagnetic based on a phase shift determined by:
the first vertical displacement distance in response to the metallic cantilever being in the non-actuated state, and
the second vertical displacement distance in response to the metallic cantilever being in the actuated state.

2. The unit cell device of claim 1, wherein, in the non-actuated state, the metallic cantilever is substantially unbent and is substantially parallel to the substrate, and in the actuated state, the metallic cantilever bends upward relative to the substrate, and wherein the first vertical displacement distance is less than the second vertical displacement distance.

3. The unit cell device of claim 1, wherein, in the non-actuated state, the metallic cantilever is substantially unbent, and in the actuated state, the metallic cantilever bends downward relative to the substrate, and wherein the first vertical displacement distance is greater than the second vertical displacement distance.

4. The unit cell device of claim 1, wherein the energy applied via the electrical contact pads comprises a bias voltage applied across the electrical contact pads, and wherein the amount of the energy applied is based on a bias voltage level.

5. The unit cell device of claim 4, wherein the bias voltage comprises a first bias voltage, wherein the phase shift is a first phase shift based on the first bias voltage, and wherein a second voltage applied across the electrical contact pads determines a second phase shift that is different from the first phase shift.

6. The unit cell device of claim 1, wherein the metallic cantilever comprises aluminum.

7. The unit cell device of claim 1, wherein the fixed resonating portion comprises a fixed outer penannular ring and a fixed disk physically coupled to the substrate, and wherein the metallic cantilever comprises an inner penannular ring positioned between the outer penannular ring and the fixed disk.

8. The unit cell device of claim 7, wherein a gap of the inner penannular ring comprises a first side physically coupled to a first anchor of the anchored portion, and a second side physically coupled to a second anchor of the anchored portion, and wherein the electrical contact pads comprise a first electrical contact pad coupled to the first anchor, and a second electrical contact pad coupled to the second anchor.

9. The unit cell device of claim 1, wherein the redirected instance is a first redirected instance, wherein the unit cell device is part of a reconfigurable intelligent surface comprising the unit cell and other unit cells arranged in an array that forms the reconfigurable intelligent surface, and wherein the phase shift of the unit cell device redirects the first redirected instance of the electromagnetic wave in a direction that creates constructive interference with a second redirected instance of the electromagnetic wave as redirected from at least one other of the other unit cells.

10. The unit cell device of claim 1, wherein the fixed resonating portion and the metallic cantilever are fabricated above a sacrificial layer, wherein the sacrificial layer is partially removed by sacrificial layer etching with respect to the fixed resonating portion, resulting in the fixed layer being physically coupled to the substrate, and wherein the sacrificial layer is fully removed with respect to the non-anchored portion of the metallic cantilever, resulting in an air gap between the non-anchored portion of the metallic cantilever and the substrate.

11. A method, comprising,
changing, by a system comprising a controller, a phase shift of a unit cell of a reconfigurable intelligent surface to redirect an electromagnetic wave impinging on the unit cell based on a target location, the changing comprising:
controlling a bias voltage applied to a bendable metallic element of a microelectromechanical systems-based resonating pattern,
wherein a first part of the bendable metallic element is anchored to a substrate, and a second part of the bendable metallic element comprises a non-anchored tip having a first vertical displacement distance, relative to the substrate, at a zero bias voltage level, and a second vertical displacement distance, relative to the substrate, that is greater than the first vertical displacement distance, at a non-zero bias voltage level,
wherein an amount of the second vertical displacement distance corresponds to an amount of the non-zero bias voltage level, and
wherein the bias voltage determines the phase shift of the unit cell.

12. The method of claim 11, wherein the phase shift is a first phase shift, wherein the target location is a first target location, and further comprising:
obtaining, by the system, information representative of a second target location; and
in response to the obtaining of the information, redirecting, by the system, the electromagnetic wave based on the second location, comprising changing the bias voltage from a first bias voltage to a second bias voltage to change the first phase shift to a second phase shift that is different from the first phase shift.

13. The method of claim 11, wherein the unit cell is part of a reconfigurable intelligent surface comprising the unit cell and other unit cells arranged in an array that forms the reconfigurable intelligent surface, and wherein the changing of the phase shift of the unit cell based on the target location redirects the electromagnetic wave to create constructive interference with the electromagnetic wave as redirected from at least one of the other unit cells, with respect to beamforming the electromagnetic wave as redirected towards the target location.

14. The method of claim 11, wherein the unit cell is part of a reconfigurable intelligent surface comprising the unit cell and other unit cells arranged in an array that forms the reconfigurable intelligent surface, and wherein the changing of the phase shift of the unit cell based on the target location creates destructive interference with the electromagnetic wave as redirected from at least one of the other unit cells.

15. A system, comprising:
a unit cell configured to redirect an incoming electromagnetic wave as a redirected electromagnetic wave, the unit cell comprising:
a substrate;
a resonating pattern corresponding to the incoming electromagnetic wave, the resonating pattern comprising:
a fixed metallic resonator;
a metallic cantilever comprising a first portion physically coupled to the substrate, and a second portion physically decoupled from the substrate, the metallic cantilever being substantially uncurved when not heated by joule heating, relative to a greater amount of curvature when heated by a non-zero amount of joule heating, wherein a resultant amount of curvature corresponds to the amount of joule heating; and
electrical contacts coupled to the metallic cantilever proximate to the first portion; and
a controller configured to selectively apply energy to the electrical contacts to selectively heat the metallic cantilever with a selected amount of joule heating, corresponding to a selected resultant amount of curvature of the metallic cantilever,
wherein the resultant amount of curvature determines a direction of the redirected electromagnetic wave.

16. The system of claim 15, wherein the first portion of the metallic cantilever is physically coupled to the substrate by respective anchors, and wherein the respective anchors are electrically coupled to respective electrical contacts of the electrical contacts.

17. The system of claim 15, wherein the controller applies a selected bias voltage or current to the electrical contacts to heat the metallic cantilever with the selected amount of joule heating.

18. The system of claim 15, wherein the metallic cantilever comprises aluminum.

19. The system of claim 15, wherein the fixed resonating portion comprises a fixed outer penannular ring, and further comprises a fixed disk physically coupled to the substrate, and wherein the cantilever comprises an inner penannular ring positioned between the outer penannular ring and the fixed disk.

20. The system of claim 15, wherein the unit cell is a first unit cell of a reconfigurable intelligent surface comprising the first unit cell and a second unit cell, wherein the selected amount of joule heating is a first selected amount, wherein the redirected electromagnetic wave is a first redirected electromagnetic wave, wherein the direction of the first redirected electromagnetic wave is a first direction, and wherein the controller selects the first selected amount of joule heating for the first unit cell, and selects a second selected amount of joule heating for the second unit cell, to create constructive interference of the first redirected electromagnetic wave with a second redirected electromagnetic wave as redirected from the second unit cell in a second direction.
